(19) United States
(12) Patent Application Publication
(10) Pub. No.: US 2015/0056383 A1
(43) Pub. Date: Feb. 26, 2015

(54) High Resolution Printing

(71) Applicant: Intrinsiq Materials Ltd., Famborough Hampshire (GB)

(72) Inventors: Jose Pedrosa, Farnborough Hampshire (GB); Daniel Johnson, Farnborough Hampshire (GB); Richard Dixon, Farnborough Hampshire (GB)

(73) Assignee: INTRINSIQ MATERIALS LTD., Farnborough Hampshire (GB)

(21) Appl. No.: 14/238,262

(22) PCT Filed: Aug. 13, 2012
(86) PCT No.: PCT/GB2012/051975

§ 371 Date: Nov. 5, 2014

(30) Foreign Application Priority Data
Aug. 12, 2011 (GB) 1113919.3

(51) Int. Cl. H05K 3/02; H05K 3/00

(52) U.S. Cl. CPC H05K 3/027; H05K 3/0091; H05K 2203/107; H05K 2203/108
USPC 427/556; 427/555; 118/620; 118/696

(57) ABSTRACT

Method for printing high resolution features on a substrate, the method comprising: depositing a nanoparticle ink, comprising metal/semi-metal nanoparticles and an adhesive compound, having a binder on a substrate; and applying a laser beam, directly on some or all of the deposited nanoparticle ink to define the print feature, wherein the laser beam is configured to remove the nanoparticle coating or binder thereby allowing the adhesive compound to bond to the nanoparticles and the laser beam is further configured to transform the ink to form a metal/semi-metal structure. The remaining uncured structure can be easily washed away using standard developer solutions such as sodium or potassium hydroxide.

### TECHNICAL FIELD

The present invention relates to apparatus for printing high resolution features with nanoparticles. In particular the invention relates to a system in which a printed layer is directly transformed by sintering or curing with a laser onto a substrate.

### BACKGROUND TO THE INVENTION

It is desirable for electronic structures and devices such as conductive tracks and semiconductor devices such as transistors to be continuously reduced in size to meet a myriad of new applications, such as printed thin film transistor technology and electrode structures for display technologies. In particular, as picture resolution capabilities of displays increase, the size of the conductive tracks decreases.

Typically, when creating high resolution features ink-jet, offset gravure or screen printing processes are used and, depending on ink/substrate interaction, can produce features which are about 10 μm (10×10⁻⁶ m) in width, although more typically feature sizes are 50 μm and above. Higher resolution features have been obtained using photosensitive or photoresist materials combined with developing and etching processes. In such processes a photoresist material is placed on a film, in the form of the desired pattern and the photoresist material is subsequently cured or hardened. The film is subsequently developed, typically using an alkaline developer solution such as sodium hydroxide, and the areas of film which are not covered by the hardened photoresist layer are removed. Such a process is multi-staged and relies on the accurate deposition of the photoresist layer to form the desired printing structure.

To overcome some of the problems with the prior art there is described a process in which high resolution features can be printed and directly cured onto a substrate, thereby removing the need for a further layer or additive.

In an embodiment of the invention there is provided a method for printing high resolution features on a substrate, the method comprising: depositing a nanoparticle ink, comprising metal/semi-metal nanoparticles and an adhesive compound, having a binder on a substrate; and applying a laser beam, directly on some or all of the deposited nanoparticle ink to define the print feature, wherein the laser beam is configured to remove the nanoparticle coating or binder thereby allowing the adhesive compound to bond to the nanoparticles and the laser beam is further configured to transform the ink to form a metal/semi-metal structure.

Optionally, wherein the laser beam is a continuous wave laser beam and/or wherein the laser beam emits in the visible or infra-red. Optionally wherein the adhesive compound comprises an adhesion promoter and surfactant. Preferably wherein the adhesion promoter and surfactant are selected from the group comprising polysiloxanes, polyacrylates, polyurethanes, epoxy based materials, polymethacrylates, maleic anhydrides, polypyrroles and flurosurfactants. Optionally wherein the nanoparticle ink comprises a metal selected from the group of copper, gold, silver, nickel aluminium, tantalum, and molybdenum. Optionally wherein the nanoparticle ink comprises a plurality of metal nanomaterials such as copper and silver, or metal and/or semimetals such as silicon and nickel. Additionally, the technology is also applicable to seed layer systems as described in patent application GB1212407.9 (the contents of which are incorporated herein) uses other metal or semimetal nanoparticles to improve adhesion. Optionally wherein the nanoparticle ink is a semi-metal and comprises silicon. Preferably wherein the silicon is doped with a dopant, such as boron or phosphorous. Optionally wherein the binder is any organic greater than C3 or C4. Optionally wherein the laser beam has a profile which is adapted to a top hat profile or improved uniformity over the typical Gaussian beam profile. Preferably wherein the laser beam is adapted through an aperture or slit mask. Preferably wherein the beam is adapted through a galvo scanner system. Optionally comprising the further step of adapting the beam through a lens system. Optionally comprising the further step of removing some or all of the untransformed ink from the substrate. Preferably wherein the step of removing some or all of untransformed ink occurs after the application of the laser onto the substrate. Preferably where the step of removing some or all of the untransformed ink occurs before the application of the laser onto the substrate. Optionally wherein multiple nanoparticle ink layers are processed with different compositions. Preferably wherein the first layer promotes adhesion and/or different layers containing different doping concentrations or species.

Optionally wherein the substrate is selected from the group comprising: PET, PI, PE, PP, PVA, PI, SiN, ITO, alumina tile, and glass. Preferably to create a pn device.

There is also provided apparatus for printing high resolution features on a substrate, the apparatus comprising: an ink depositing device for depositing a nanoparticle ink comprising metal/semi-metal nanoparticles and a surfactant and/or adhesive compound, having a binder onto a substrate; a laser configured to apply a laser beam, directly on some or all of the deposited nanoparticle ink to define the high resolution print feature; and a mask or focusing means configured to adapt the laser beam to produce a focussed laser spot; wherein the laser beam frequency is selected so as to remove the nanoparticle coating or binder of the nanoparticle ink thereby allowing the adhesive compound to bond to the nanoparticles and the laser beam is further configured to transform the ink to form a metal/semi-metal structure, thereby producing a metal/semi-metal structure the width of the laser spot.

Further aspects of the invention will be apparent from the appended claim set.

### BRIEF DESCRIPTION OF THE FIGURES

Embodiments of the invention are now described, by way of example only, with reference to the accompanying drawings in which:

FIG. 1 is a flow chart of a method to print high resolution features according to an aspect of the invention;

FIG. 2 is a schematic representation of forming a high resolution feature from a printed film of nanoparticle ink on a substrate;

FIG. 3 is a schematic representation of forming a high resolution feature from a printed film of nanoparticle ink on a substrate;

FIG. 4 is a schematic representation of refining a printed image to form a high resolution feature;

FIG. 5 is a schematic representation of high resolution printing with a material which has been coated via electroplating or electroless deposition;

FIG. 6 is an SEM image of high resolution features formed according to an aspect of the invention;

FIG. 7 is a schematic of the apparatus used in an embodiment of the invention;

FIG. 8 is a schematic representation of the lens configuration;

FIG. 9 is a schematic representation of the apparatus with multiple lasers and a fibre optic system for printing high resolution features; and

FIG. 10 is a schematic representation of the apparatus with multiple lasers.

### DETAILED DESCRIPTION OF AN EMBODIMENT

According to an aspect of the invention there is provided an apparatus to print high resolution features. The process, according to an aspect of the invention, described allows for either:

1. Refinement of a printed image to track resolutions down to 0.5 μm; or
2. Production of high resolution images directly from roller coated films or equivalent deposition technology, i.e., where large areas of the substrate are completely covered with the required ink material.

In particular the method described allows for high resolution printing of lines, with a width in the range of 0.5-100 microns, preferably high resolution features of 5 microns or less.

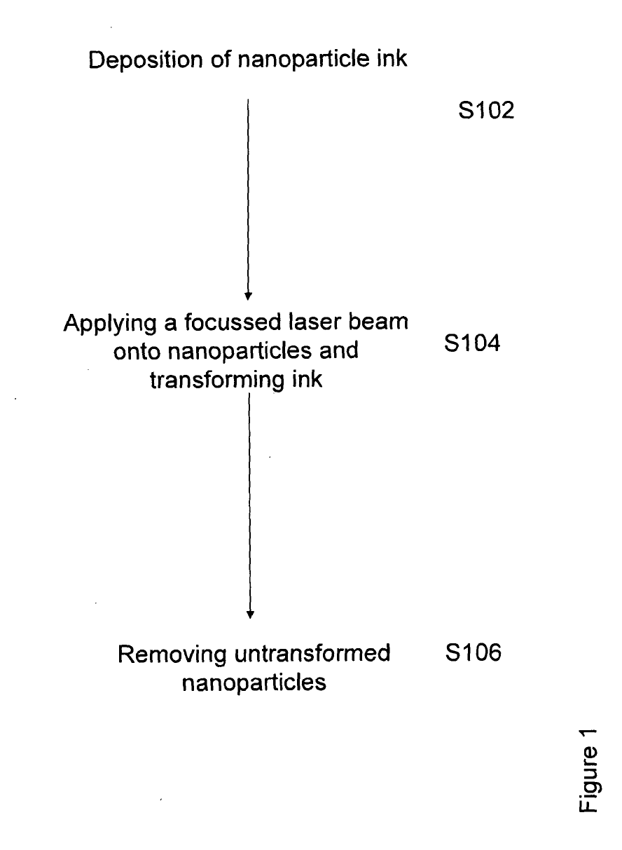

FIG. 1 is a flowchart of the general process for printing a high resolution feature according to an aspect of the invention.

There is shown the steps of: depositing a nanoparticle ink in step S102; scanning a laser beam across the deposited ink to transform the ink via sintering or curing at step S104; and removing the untransformed ink at step S106.

The printed structures that can be formed by the present method are made of a metal or semi-metal. Suitable metals include, but are not limited to, copper, gold, silver, nickel, aluminium, tantalum, molybdenum, etc. Semi-metals including silicon can also be used, furthermore silicon particles that have been doped to provide semiconducting behaviour (for example with phosphorous, boron or arsenic) are also suitable. Therefore, the present method can be used in production of both electronic structures and semiconducting devices.

The nanoparticle ink used in the present invention comprises a metal or semi-metal composition with a binder or coating (typically organic). The binder or coating is present in inks to eliminate or reduce oxidation, prevent agglomeration and to maintain the surface area, which confers many of the advantageous properties of nanoparticles. The nanoparticles used in the ink formulation can be between 1-500 nm. The size refers to the diameter of the particle as measured by known measurements such as SEM or dynamic light scattering techniques. Advantageously, therefore, the present invention can be implemented for a wide range of nanoparticle inks including larger particles which are often cheaper to produce and/or purchase. An example of a suitable ink is the commercially available CI-002 formulation sold by Intrinsiq Materials™. Preferably the ink comprises an adhesive compound or surfactant to promote breakdown and solidification of the deposited material.

The nanoparticle ink is deposited onto a substrate at step S102. The ink is deposited by ink-jet deposition method though other suitable deposition methods such as offset-lithography, screen printing, indirect and direct gravure, flexography, aerosol, etc., may be used. The binder and/or coating present in the nanoparticle ink ensures an even distribution of the ink. The deposited layer is typically between 0.05-50 μm. The size of the deposition layer can be varied according to the user's requirements.

At step S104 a focussed laser beam is scanned across the deposited ink. The scanning of the laser occurs in such a manner as to define the pattern to be printed. Accordingly, to ensure high resolution printing the beam is focussed, or masked, to produce a spot size of between 0.5-100 μm, preferably 5 μm or less, depending on the size of feature required. As only the ink that is impacted by the laser is cured, by focusing or masking the laser, structures of 5 μm or less may be formed. The size of structure formed being dependent on the size of the laser spot. Therefore, the present invention provides a method and apparatus for producing high resolution features, whose size is determined by the focusing or masking of the laser beam.

In further examples the laser is emitted directly onto the deposited ink i.e., no focusing or masking of the beam occurs. The pattern of the scan of the laser defines the feature and is controlled by known laser guiding means or a mask.

As the laser scans across the substrate, the coating of the nanoparticles and/or binder materials are removed, typically volatized, by the incident laser light. The high surface area of the nanoparticles means that the energy required to transform the nanoparticles in the ink, such as by sintering or curing, is less than for bulk materials. Therefore, as the laser scans across the deposited layer, not only does it remove the coating/binding it also causes a transformation of the material from the individual metal/semi-metal nanoparticles to form a metal/semi-metal structure, in the form of a densified metal or semi-metal film (depending on the material of the nanoparticle ink). As the laser can be highly focused to define a high resolution laser spot, through for example the use of lenses, the densified film structure that is formed is localised to the areas impacted by the laser. The high degree of accuracy with which the laser can be directed results in the formation of the high resolution print structures.

In a preferred embodiment the laser used is a continuous wave laser operating in the visible or infra-red range. This laser allows for a continuous energy source which promotes sintering/curing, reducing the opportunity for oxidation and removal of nanoparticle organic binder systems (such as employed in CI-002).

The use of continuous lasers is advantageous for curing as they offer lower average power. The high peak energy of pulsed lasers makes them more suitable for ablation rather than the sintering or curing which is preferred. Pulsed UV lasers are found to lead to absorption resulting in the curing/sintering only taking place in the top layers, and accordingly the lower layers of deposited material remain unaffected. The printed layer at the interface is therefore partially or substantially uncured resulting in the layer being easily washed away. These problems are advantageously overcome by the use of the continuous wave lasers.

Therefore, advantageously the present invention allows for the production of high resolution features in a single layer process. In particular the invention avoids the need for an extra layer, such as a photoresist layer.

Furthermore, the invention does not require the use of etchants unlike in photoresist methods where the etchants are used to remove the unprotected structure. This is advantageous as it simplifies the production process and it is known that etchants can result in excessively sloped tracks or undercut, whereas the use of lasers to directly transform the material allows for well defined edges to be formed. In particular apertures or lens systems, including aspheric and “freeform” lenses can be employed in certain embodiments to convert the laser beam profile from the typically Gaussian to a more uniform “top hat” profile and therefore produce sharp profile edges. It is found that the uniform “top hat” profiles results in well defined feature edge profiles, edge features that are 65-95° to the substrate surface, and therefore avoids problems associated with undercut/sloped tracks which are known to occur with photoresist materials.

Preferably the deposited ink is formulated so that the sintering or curing by the laser promotes breakdown of the ink and solidification of the material. It is found that selection of adhesive compounds, surfactants, adhesion promoters and surfactants such as silanation compounds can provide improved adhesion when these compounds are degraded to form glassy, ceramic type structures. Such formulations are particularly preferable as when they are sintered or cured they form structures which promote breakdown of deposited material, thus ensuring that all the deposited material is transformed, and there is good adhesion to the surface thus ensuring that the resultant material remains on the substrate even after the washing process.

The ink in an embodiment contains dispersion stabilisers such as Polyvinylpyrrolidone (PVP). Dispersion stabilisers help maintain the integrity of the structure during the curing process. In further embodiments other known dispersion stabilisers are used.

In an embodiment improved adhesion on glass and PET is obtained from the use of the following, although not exhaustive, compounds (including all industrial additives using these types of promoters); polysiloxanes, polyacrylates, polyurethanes, epoxy based materials, polymethacrylates, maleic anhydrides, polypyrroles and flurosurfactants.

Typical examples include: Vinylbenzylaminoethylaminopropyltrimethoxysilane; Mercaptopropyltrimethoxysilane; Aminoethylaminopropyltrimethoxysilane-Methacryloxypropyltrimethoxysilane; Glycidoxypropyltrimethoxysilane; Bis-Triethoxysilylpropyldisulfidosilane; Hexamethyldisilazane (3,4 epoxycyclohexyl)-ethyltrimethoxysilane; Glycidoxypropylmethyldiethoxysilane; Glycidoxypropyltriethoxysilane; 3-methacryloxypropylmethyldimethoxysilane; 3-methacryloxypropyltrimethoxysilane; 3-methacryloxypropylmethyldiethoxysilane; 3-methacryloxypropyltriethoxysilane; 3-acryloxypropyltrimethoxysilane; N-2(aminoethyl)3-aminopropylmethyldimethoxysilane; N-2(aminoethyl)3-aminopropyltrimethoxysilane; N-2(aminoethyl)3-aminopropyltriethoxysilane; 3-aminopropyltrimethoxysilane; 3-aminopropyltriethoxysilane; N-phenyl-3-aminopropyltrimethoxysilane; 3-chloropropyltrimethoxysilane; 3-mercaptopropylmethyldimethoxysilane; 3-isocyanatopropyltriethoxysilane; Tris(3-(trimethoxysilyl)propyl)isocyanurate; N-(3-methyldimethoxysilylpropyl)diethylenetriamine; N-(3-methyldiethoxysilylpropyl)diethylenetriamine; Methyldimethoxysilylpropylpiperazine; Methyldiethoxysilylmethylpiperazine; Trimethoxysilylpropylmorpho line; Methyldimethoxysilylpropylmorpho line; Hexanediaminomethyltriethoxysilane; Hexanediaminopropyltrimethoxysilane; [3-(trimethoxysilyl)propyl]aminocyclohexane; 3-thiocyanatopropyltriethoxysilane; 3-ureidopropyltrimethoxysilane; 1-[3-(Triethoxysilyl)propyl]urea; 1-[3-(Triethoxysilyl)propyl]urea; 2-(3,4-epoxycyclohexyl)-ethyltrimethoxysilane; 2-(3,4-epoxycyclohexyl)-ethyltriethoxysilane; 3-methacryloxypropyltrimethoxysilane; Methacryloxytrimethoxysilane 3-methacryloxypropyltriethoxysilane; 3-methacryloxypropylmethyldimethoxysilane; 3-methacryloxypropylmethyldiethoxysilane; Methacryloxymethyltriethoxysilane; Methacryloxymethyl(methyl)dimethoxysilane; Methacryloxymethyl(methyl)diethoxysilane; 3-Acryloxypropyltrimethoxysilane; 2-cyanoethyldichloromethylsilane; Trimethyl(methylethylketoxime)silane; Tetra(methylethylketoxime)silane; Di-tertbutoxy-diacetoxysilane; Dimethyldiacetoxysilane; Triacetoxymethysilane; Tetraacetoxysilane; Ethyltriacetoxysilane; Vinyltriacetoxysilane; Bis(trimethylsilyl)acetylene; N,O-Bis(trimethylsilyl)acetamide; Trimethylsilyl-1,2,4-triazole; 1-(trimethylsilyl)imidazole Tetra(acryloxy-ethoxy)silane; 5,5′-dimethyl-3,3′-bis(trimethylsilyl)biphenyl; Tertbutylcyclopentadienyltrimethylsilane.

Ink formulations may include one of these materials or a plurality of combinations. Adhesion promoters may also include other nanoparticle systems as described in patent application GB1212407.9.

In a further embodiment, and where thicker layers are required, a multi-stage ink process may be used, whereby; the first ink printed has a high percentage of adhesion promoter and is less conductive than a second layer which has a much higher metal/semi-metal concentration and therefore provides the conductive layer. Materials can be jointly transformed generally requiring the use of visible or infra-red continuous wave lasers.

In further embodiments a lens array is used to control the beam profile and alter the magnification of the beam (preferably by masking or focusing the beam, to define a high resolution laser spot), thereby allowing a range of structures of densified metal/semi-metal of different dimensions, for example between 0.5 μm-100 μm. Therefore the lens array produces high resolution features, preferably 5 μm or less, to be produced from the same laser configuration. Such an array allows for different apertures to be employed for each magnification lens system to obtain the desired energy profile including reducing non-uniformity. In further embodiments the lens array comprises multiple lasers and multiple lens/aperture configurations that are driven simultaneously to produce the desired image. Preferably each laser beam is masked or focused, though other methods may be used, to define a laser spot and is able to produce high resolution features. Such features may be 5 μm or less in width. This process allows for faster production rates, allowing multiple structures, of varying dimension, to be sintered simultaneously. Fiber optic systems are particularly well suited to this application as relatively lower power lasers can be readily focused down to create sufficient energy per unit area to create the required structures. Each fiber optic is driven by a laser diode and then bundled together and fed to a head, containing a lens array, that scans across the surface and allows simultaneous laser sintering of multiple features of different dimensions. This system would be particularly suitable for applications needing smaller line spacing, e.g., 2 mm or closer

Alternatively, for applications that require a larger line spacing (e.g., solar applications) a configuration that uses a number of solid state laser diode components that can be driven independently and with each diode having a separate lens/aperture arrangement may be suitable. When integrated with software, this again allows multiple structures to be drawn to the desired image.

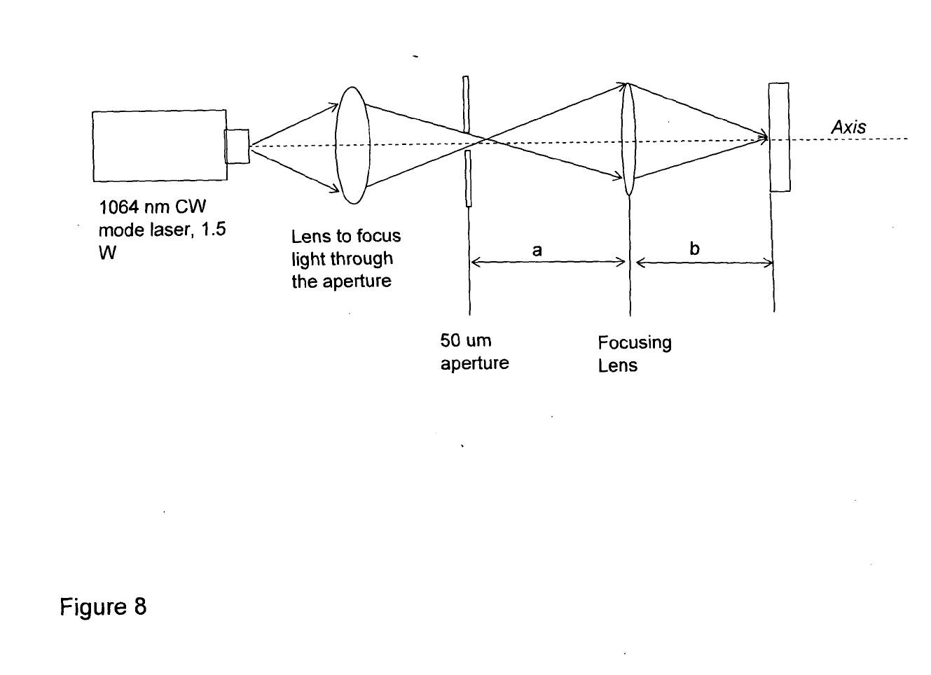

Such a lens array in an embodiment includes an initial focusing lens to concentrate the laser beam onto an aperture that is variable in size (which controls both beam intensity and uniformity of beam profile) and a final focusing lens to produce finely resolved track features. The form of a typical lens array is discussed in detail with reference to FIG. 8.

Furthermore the invention allows for the control of the strength of the laser, either through varying the voltage or lenses/masks or choice of wavelength. In particular it is found that by shinning the laser onto the nanoparticle ink too much will result in the ink ablating rather than curing or sintering. Therefore, by selection of the appropriate laser strength and wavelength it is possible to ensure that the substrate remains undamaged whilst the ink is transformed to the densified metal/semi metal structure.

Once the laser has finished scanning the substrate and the desired image has been printed the untransformed material is removed at step S106. As the ink which has been scanned by the laser beam has been transformed, typically by curing or sintering depending on the strength of the laser and length of exposure, the properties of the transformed densified metallic structure differ from the untransformed structure.

Therefore, it is possible to select washing formulations and processes to remove untransformed regions whilst having no, or negligible, impact on the transformed regions. Such washing formulations are well known in the art of photolithography. A solvent able to dissolve binders associated with the ink or a solvent able with a source of agitation to rinse away loosely bound material containing little or no binder, can be used as an appropriate wash. This may also include an acid such as carboxylic acid.

It is found that the present method has flexibility and is particularly suitable for a number of substrates including PET, PI, PE, PP, PVA, PI, SiN, ITO, alumina tile, and glass. Furthermore, the choice of substrate and ink can be used to create different materials. Dielectric materials can be formed by selection of an appropriate substrate and ink. A typical substrate may be glass sheet or alumina tile or a thin sheet of plastic. The ink is formulated, in the known manner, to adequately wet the surface of these and to bind the transformed ink to them whether using the cured and sintered particles alone or by the ink containing additional binding agents. Suitable examples include silanes for glass or acrylic polymers for PET, etc. The binder itself can be dielectric which becomes cold sintered or melted into a dense and adherent mass suitable for the chosen substrate, for example nano-titania or silicates, or a hot melt plastic. The specific binders and adhesives and/or surfactants required for a particular substrate are known to those skilled in the art.

Therefore, the present application provides an improved method for producing high resolution lines compared to other systems. In particular, the direct transformation (curing, sintering or otherwise) of the material by the laser allows for higher resolution features, avoids the need for further layers such as photoresist layers and can be performed on large scales/high volumes as it requires fewer stages to produce. Furthermore, by controlling the laser beam profile, near vertical edges can be formed thus improving the resolution of the image.

Further advantages can result from the appropriate selection of laser wavelength. If a thicker deposit of material is used, a higher wavelength laser (such as one operating in the IR) is selected to penetrate further into deposited layer. Depending on the composition of the nanoparticle ink, the laser wavelength is selected to couple with the ink formulation additives thus causing evaporation/dissociation of the organic materials from the nanomaterials. Furthermore selection of the appropriate wavelength of laser is used to enhance surface adhesion between the substrate and the metal/semiconductor/semi-metal film by modification of species at the interface of substrate and film.

Advantageously, the selection of the laser wavelength along with the focussing (or masking) of the laser allows for the production of high resolution features which are cured the entire depth of the deposited layer.

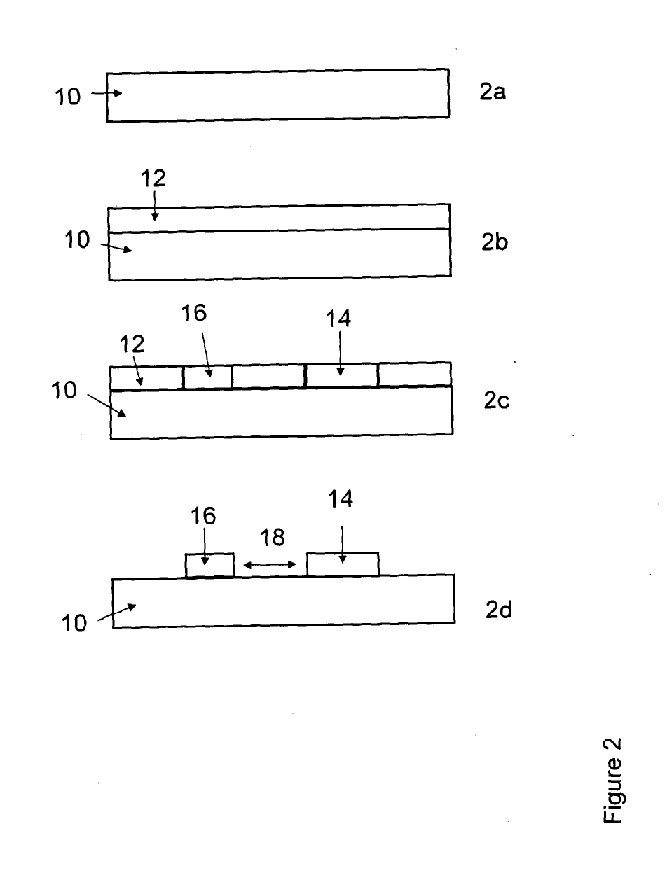

FIGS. 2a to 2d are a schematic representation of forming a high resolution feature from a printed film of nanoparticle ink on a substrate. There is shown the substrate 10, nanoparticle ink 12, a first cured layer 14 and second cured layer 16, and the washed off uncured region 18.

In FIG. 2a, the substrate 10 is uncovered. In FIG. 2b the substrate has had a layer of nanoparticle copper ink 12 with an organic binder deposited onto it as per step S102 of FIG. 1. In an example, the copper ink 12 is deposited on the substrate via roll coating. The binder in the present example is organic, of C₄ upwards. In further embodiments a binder of C3 may be used. In FIG. 2c the laser (not shown) has scanned and cured two regions 14 and 16 to form a densified metallic film structure as per step S104 of FIG. 1.

In FIG. 2d, the substrate 10 has been washed as per step S106 of FIG. 1 removing the uncured region 18 and leaving the cured regions 14, 16 to define the two high resolution features making a copper structure. Typically the uncured region gap 18 would be of the order of 15 μm. The ink formulation used in FIG. 2 comprises an adhesive compound as described above to promote solidification of the material.

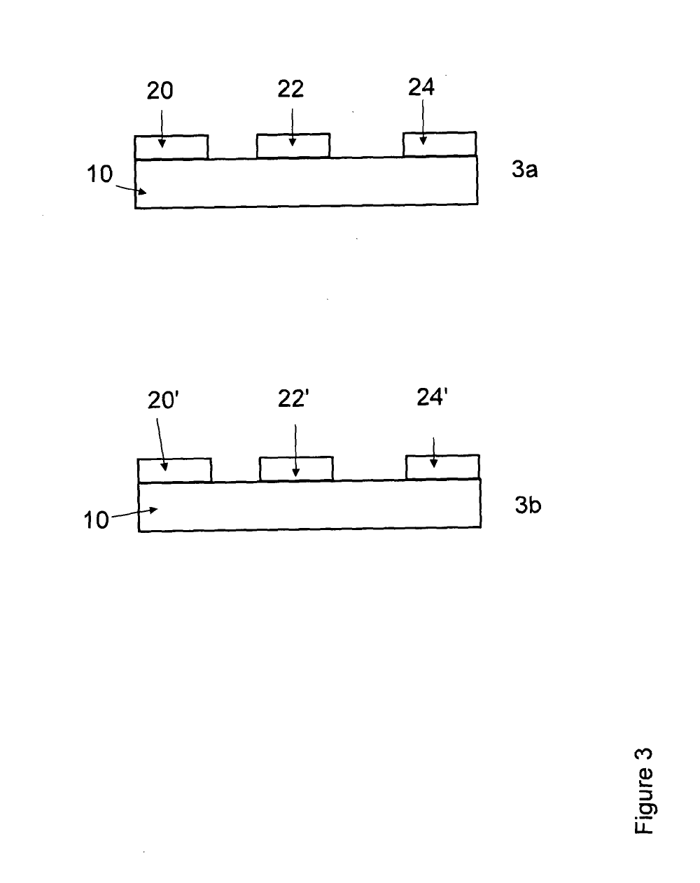

FIG. 3 is a schematic representation of forming a high resolution feature from a printed film of nanoparticle ink on a substrate. There is shown the substrate 10 and three ink regions 20, 22, 24.

In FIG. 3a the substrate 10 has been coated with the ink 20, 22, 24 and the untransformed ink has been ablated to leave behind the desired printing structure. The ablation may occur with a very high energy laser or electron beam. Alternatively, a broadband photonic source such as a xenon lamp may be used instead of a laser, though due to their Gaussian profiles these are less preferred. The specificity of the ablation using a broadband and wide beam mechanism may be accomplished by coating the printed surface with materials having either high or low reflectivity, thus significantly adjusting the absorbed energy density to suit conditions for ablation or indeed annealing of the ink.

The laser (not shown) then transforms via curing or sintering the remaining unablated ink to form the metal structure 20′, 22′, 24′. In the present example, the wavelength and energy of the laser are chosen so that the substrate remains undamaged but the ink is transformed.

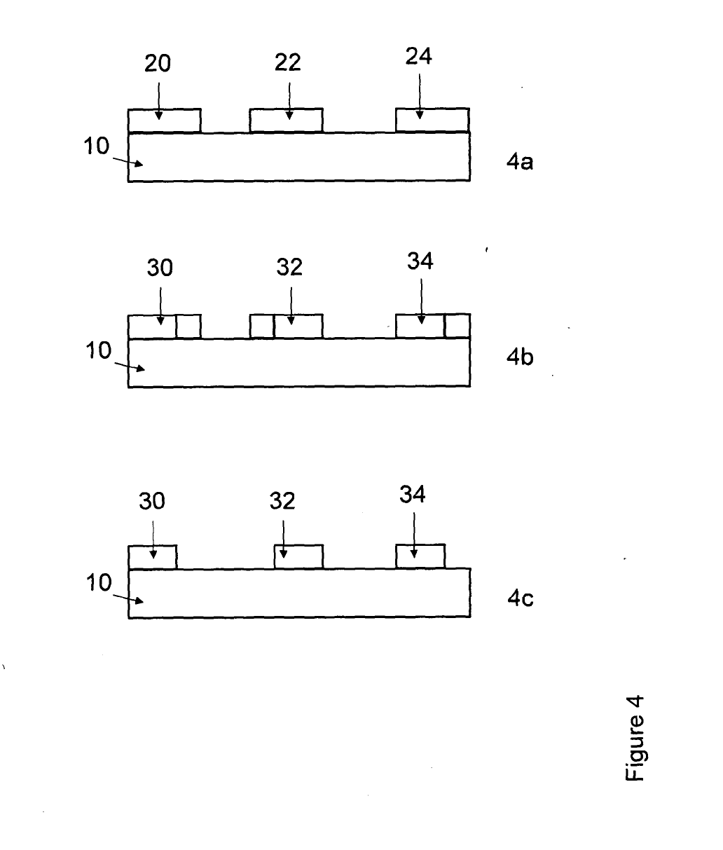

FIG. 4 is a schematic representation of refining a printed image to form a high resolution feature. FIG. 4a shows a substrate 10 and three ink regions 20, 22, 24.

As in FIG. 3, parts of the ink layer have been ablated to leave the three ink regions 20, 22, 24. To refine the ink regions 20, 22, 24 in order to accurately form smaller structures there is provided an alignment system, to accurately align the laser. In such a system one or more printed features, such as a registration mark, are printed, at preferably known locations, on the surface. A camera (not shown) is used to identify the registration marks on the surface, and communicates with a computer (not shown) as part of a computer controlled coordinate system. The computer is connected to a motor configured to move the laser in the x-y plan, and the computer is configured to control the motor. In an alternative embodiment the motor is configured to move the sample being cured in the x-y plane. The computer is configured to determine the relative offset between the sample and the laser using the registration image (or other type of printed feature) and adapted to move the sample and laser, using the motors, so that they are in alignment.

The registration mark may also be printed with the printed image at the same time to allow improved registration, or the printed feature may be aligned to a registration mark and that mark is used as a common location for all subsequent alignments. In such an example of the invention, the laser (or sample) moves in the x-y plane to create the desired pattern. The laser, or sample, is moved by the motor which is controlled by the computer. The laser beam or sample may move to achieve the lasing pattern using a either motor driven translation apparatus to which the laser or connected lens device or lased sample is attached or alternatively using a motor driven galvo mirror able to deflect the output beam of a fixed position laser output beam. Thus, the laser beam is incident on the printed pattern of ink and transforms that part of each ink region. The cured regions of the three ink regions 20, 22, 24 are shown as 30, 32 and 34 respectively. Due to the uniform, non-Gaussian wavefront the laser can accurately sinter specific features of each region creating very high resolution features. Typically an ink region 20 can be 10 μm in width and the sintered region 30 approximately ˜5 μm.

In FIG. 4c the untransformed regions are washed off as per step S106 of FIG. 1 leaving the transformed high resolution regions.

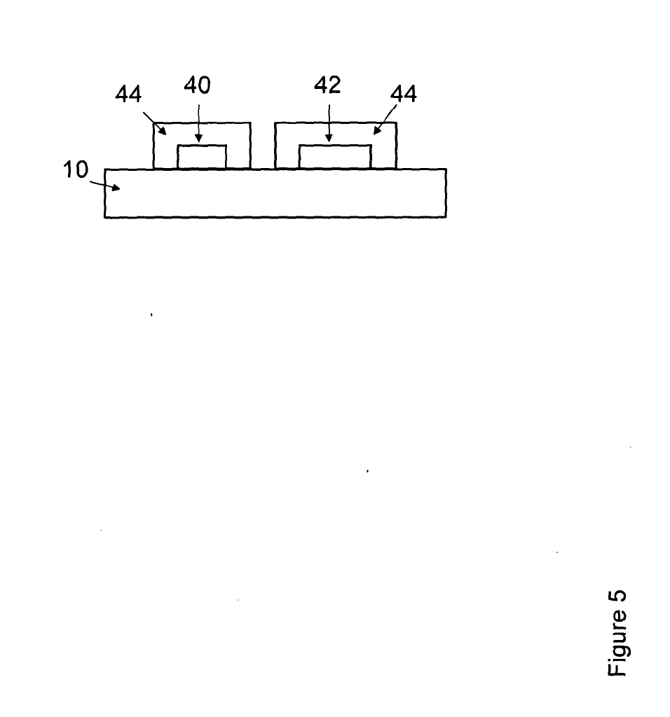

FIG. 5 is a schematic representation of high resolution printing with a material which has been coated via electroplating.

There is shown the substrate 10, with two cured regions of copper nanoparticle ink 40 42, the cured regions having a copper coating 44.

In the example shown the deposited ink is a copper nano-particulate ink with an adhesive binder. The ink has been cured using the methods described above to form two high resolution features and has coated with copper via known electroplating methods.

In further examples other inks and coatings may be used.

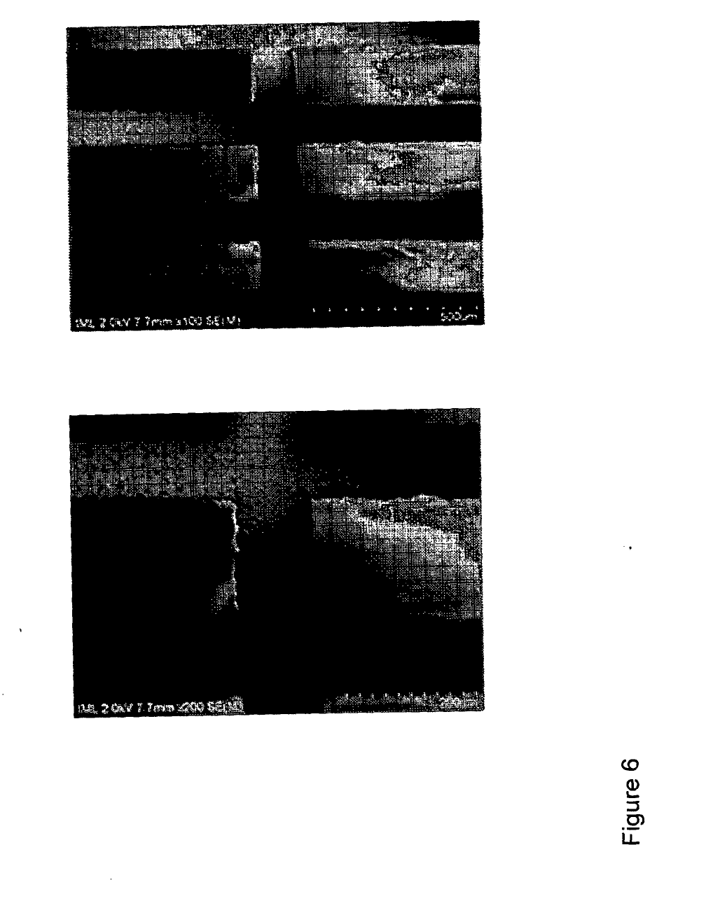

FIG. 6 is an SEM image of high resolution features formed according to an aspect of the invention.

The image shows the defined edges which are obtained by the present invention. In the example shown a 1064 nm continuous wave laser was used to generate a track width of 3.8 um.

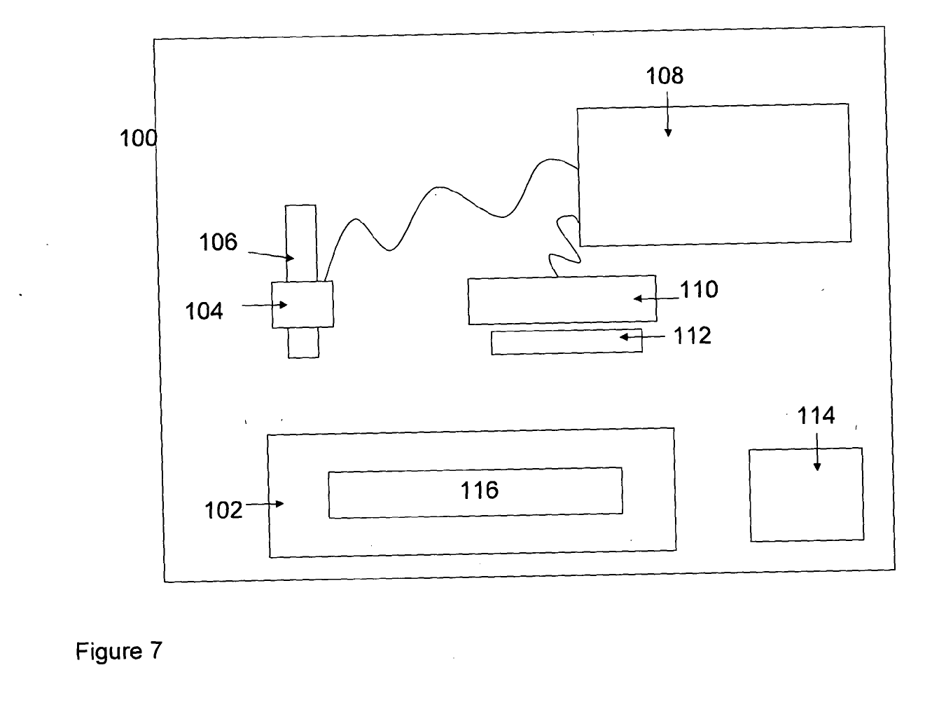

FIG. 7 is a schematic diagram of the apparatus used in an embodiment of the invention.

There is shown a chamber 100, in which is placed a curing table 102, above which are a printer 104, having an ink source 106 and connected to a central computer 108, the computer 108 also connected to a laser 110, and an optics unit 112. There is also a wash unit 114. The substrate 116, such as glass, is placed on the table 102.

The computer 108 controls the printer 104, in the example shown the printer is an inkjet printer that has an ink source 106 of copper ink nanoparticles with an organic coating. The computer 108 is connected to the printer 104 via known protocols and over a wired or wireless connection.

In use, a user inputs the choice of ink 106, deposition layer depth, substrate 116 and the desired printed pattern into the computer 108. The inkjet printer 104 in controlled by the computer 108 and deposits the unaltered nanoparticle ink 106 onto the substrate 116.

The ink 106 is deposited so as to cover the entire substrate 116, and the desired pattern is formed by transforming the ink 106 using the laser 110. In another, ink saving, embodiment, the printer 104 roughly defines the desired pattern on the substrate 116 and the laser 110 refines the pattern by only transforming the desired tracks. This results in less wasted ink as areas which are known in advance not to have any printed features are not covered in ink 106.

The computer 108 also determines from the input of ink 106 and substrate 116 the required laser wavelength, intensity and beam size. The required wavelength and intensity are dependent on the choice of ink, deposition depth and substrate. Suitable values are stored in a memory, as a look up table from previous experimental data, or calculated. The beam size is dependent on the inputted printed pattern, with a high resolution feature requiring a fine beam.

The computer 108, selects the appropriate laser(s) 110 as well as optics. The intensity of the laser is set by either varying the voltage or amps supplied to the laser 110, and/or the amount of time the laser 110 remains focussed on a particular spot. The computer 108 sets the scan pattern and actuates the laser 110, through known laser guiding means, across the substrate 116 in the desired pattern. The scanning results in the ink 106 being transformed from the copper ink nanoparticles to a copper densified film structure or matrix.

The substrate 116 is then placed in the wash unit 114 to remove the unwanted ink 106. The wash is a solvent molecule with functional chemical groups attached that are similar or the same groups able to dissolve away molecules in the untreated copper, though other forms of wash may be used. Thus the copper ink 106 may be formulated to contain binder molecules tuned to the specific solvent in the rinse and such that treated copper owing to its morphology and revised binding chemistry is unable to yield to this same rinse step solvent.

In further embodiments, to produce structures or films with zero oxide content the processing occurs in an inert atmosphere. The chamber 100, further comprises a pump (not shown) from which an inert gas, such as neon, is introduced into the chamber 100. As the laser cures or sinters the ink, the organic binder is volatized which can result in oxidisation of the metal. It is found that conducting the process in an inert atmosphere results in little or no oxidisation.

In further embodiments, the table 102 is placed on a heat sink (not shown) or the production process may occur in a ventilated environment in order to remove the excess heat produced by the laser sintering/curing process.

FIG. 8 shows a schematic representation of a focussing array used to produce high resolution features, such as those shown in FIG. 6.

There is shown the laser 110, the optical unit 112, comprising a first focussing lens 120, an aperture 122, and a second focussing lens 124. There is also shown the substrate 116 upon which the high resolution feature is to be printed.

The laser 110 is a 1046 nm continuous wave laser which emits at 1.5 mW. In other embodiments other lasers may be used. The laser 110 emits towards the first focussing lens 120 which is configured to focus the laser through the aperture 122. The lens 120 therefore focuses a significant portion of the light through the aperture. In a preferred embodiment, in order to produce a high resolution feature the aperture size is 50 μm and light which is not focussed by the lens is blocked by the aperture. At a distance “a” from the aperture 122 a second focussing lens 124 focuses the light to a focal point at a distance “b” from the lens. To produce high resolution features, the material being cured is placed at the focal point of the lens. The focal point of the lens is dependent on the lens 124 used.

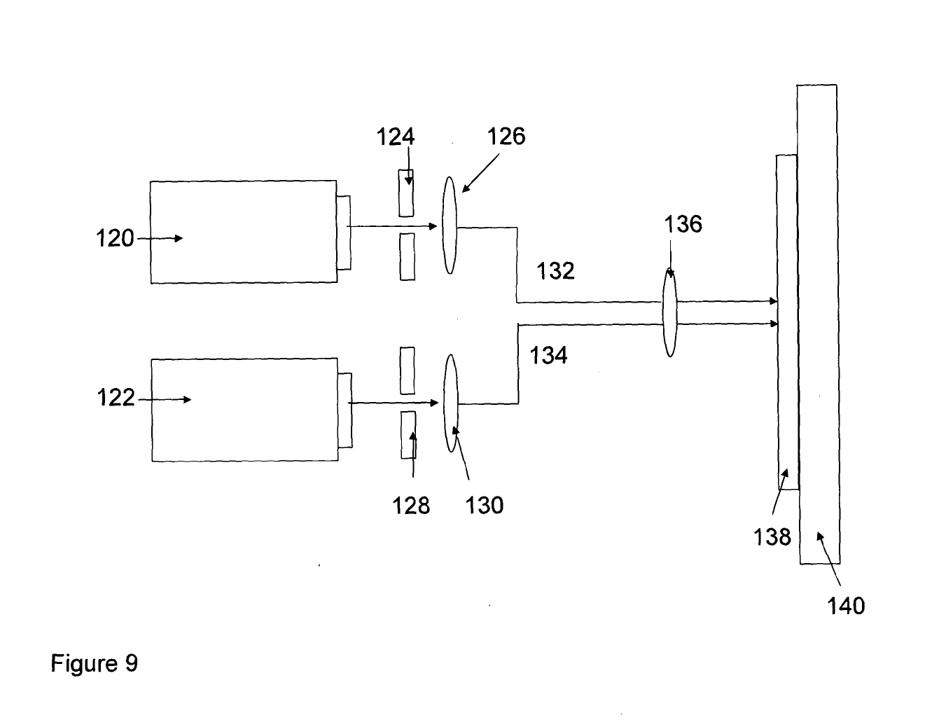

FIG. 9 is a schematic representation of a printing apparatus, used to print high resolution features. The apparatus comprising multiple lasers and a fibre optic system to simultaneously print multiple high resolution features. Such an arrangement is therefore suitable in high production environments.

There is shown in FIG. 9 a printing apparatus with two lasers. Two lasers are shown for clarity purposes and in further examples of the invention more than two lasers are present in the apparatus.

There is shown two lasers 120 122. The first laser 120 has a first aperture system 124 and collimating lens 126. The second laser 122 also has a second aperture system 128 and collimating lens 130. The light from the first collimating lens 126 is guided along a first fibre optic cable 132 and the light from the second collimating 130 is guided along a second fibre optic cable 134. The fibre optic cables 132 134 thereby define a fibre optic bundle which directs the light from the lasers 120 122. The light from the fibre optic cables 132 134 pass through a focussing lens 136, to define a laser spot on the sample 138 which is placed on a substrate 140 or sample holder. In further embodiments one or more of the focussing lenses 150 152 are replaced by masks (not shown) to define the laser spot.

In further examples, the one or more of the apertures 124 126 and one or more of the lenses 126 130 136 may be dispensed with an the light from the lasers 120 122 is guided directly by the fibre optic bundle.

The individual fibre optic cables are preferably individually controllable thereby providing greater control of the apparatus. In an example the fibre optic cables are moved by a motor (not shown) though any other suitable means may be used.

The use of fibre optic cables 132 134 to define a fibre optic bundle allows for high resolution features to be printed simultaneously in close proximity to each (with gaps of the order of millimetres). The individual fibre optic cables 132 134 allows for the closer spacing of such features than would be otherwise possible. This is found to be particularly beneficial when creating, for example, circuit diagrams.

In an example of the invention, the desired shape to be drawn, e.g. circuit diagram, is inputted into a controlling computer (not shown). The computer is configured to control the position the of the cables (for example through the use of a motor, not shown) in order to define the desired pattern. Therefore, by using multiple lasers 120 122 the desired pattern can be quickly and accurately drawn onto the sample 138.

The apparatus shown in FIG. 9 is therefore particularly beneficial when printing multiple high resolution features in close proximity.

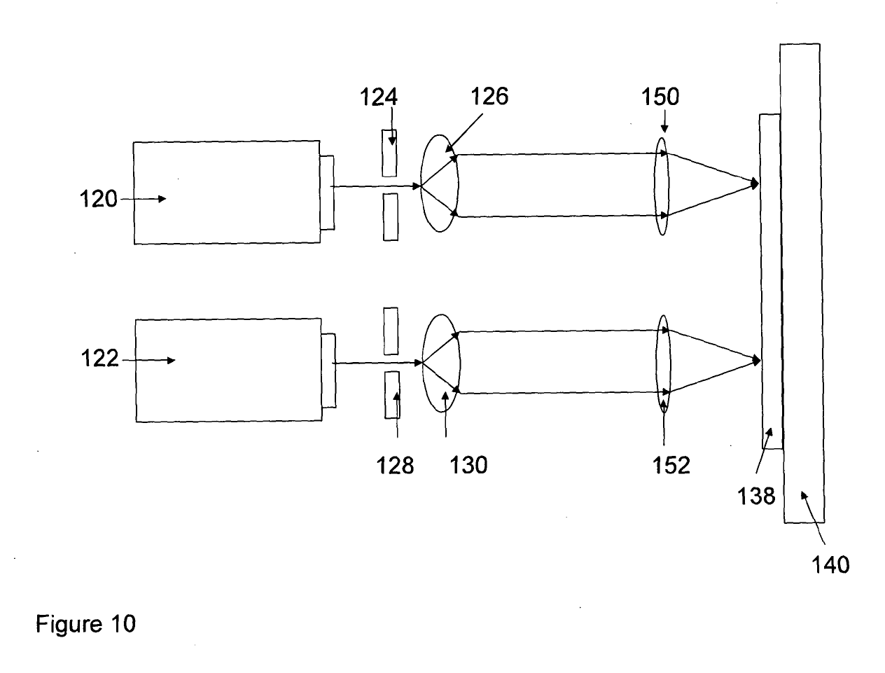

FIG. 10 is a further example of the apparatus according to print high resolution features. The apparatus comprising multiple lasers to simultaneously print multiple high resolution features. Such an arrangement is therefore suitable in high production environments.

As with the example of the invention shown in FIG. 9, only two lasers are shown for clarity. In further examples of the invention more than two lasers are used.

There is shown two lasers 120 122. The first laser 120 has a first aperture system 124 and collimating lens 126. The second laser 122 also has a second aperture system 128 and collimating lens 130. The light from the first collimating lens 126 is focussed by a first focussing lens 150 and light from the second collimating lens 130 is focussed by a second focussing lens 152. The first and second focussing lenses 150 152 direct the laser, to define a laser spot, onto the sample 138 which is placed on a substrate 140. In further examples the apertures 124 128 and first and second collimating lenses 126 130 are dispensed with and the light from the first and second lasers 120 122 passes directly to the focussing lenses 150 152.

In further embodiments one or more of the focussing lenses 150 152 are replaced by masks (not shown) to define the laser spot.

Preferably, each lens (or mask) is individually controllable in order to define the feature printed by the apparatus. The lenses 150 152, in an example of the invention, define an array of lenses which is controlled to define the printing of the high resolution features.

The apparatus shown in FIG. 10 is preferably used in embodiments where the defined features are printed with a greater separation. For example, in solar cells where the high resolution features are spaced apart.

Therefore, the apparatus in FIG. 10 is preferably used when the features are spaced relatively far apart.

In the apparatus shown in FIGS. 9 and 10, the laser diodes can be switched individually, or simultaneously. The laser diodes 120 122 are controlled by a controller (not shown) such as computer. The controller is preferably enabled to receive inputs such as circuit design diagrams defining the circuit to be drawn. In the apparatus shown the lasers are focussed down, so relatively low power and inexpensive diodes can be used.

In further examples the width of the output beam of the lasers is modified through the use of lenses. The lenses are selected to disperse the laser spot so as to define laser spots to define a line of up to 100 microns in width. Inn further examples the width of the line is varied according to lens selection. As multiple lasers can be used, and actively selected to be turned on simultaneously, two or more lines could be drawn at once to define a larger line. For example, two lines each of 50 microns in width may be drawn on the substrate. By positioning the fibre optic cables, the lasers can define a single line of 100 microns in width. Similarly, other line widths may be drawn by positioning of the fibre optic cables or focussing lines.

In further examples of the invention, the substrate 140 is moved and the laser imaging system is fixed in position. In further examples the imaging system (in particular the focussing lenses 150 152 or fibre optic cables 132 134) are located in a lens array mounted in a head (not shown) that scans across the surface to cure the sample 138 placed on the substrate 140.

The invention described has applications across a number of areas where high resolution printing is required. Advantageously, the invention allows for both low and high volume production. Thus the invention is suitable for large scale manufacture as well as workbench production.

In particular the invention is found to be suitable for use in:

(i) Production of conductive structures, such as bus bars or electrode structures, for touch screen display technologies used in tablets, smart-phones and industrial screens used in manufacturing processes, medical devices and other applications.
(ii) As an alternative to transparent conductive oxide (TCO) technologies such as ITO, ATO and FTO. In such embodiments the track dimensions are sufficiently reduced in width they are not visible to the human eye but are found to provide sheet resistivity comparable to TCO structures.
(iii) Solar cell electrode structures. In such technologies there is a drive to low width electrode structures to minimise shadowing losses and ensuring the maximum light intensity can reach the solar cell. Therefore the use of small scale features, such as those described above, are particularly beneficial.

1-34. (canceled)

35. A method for printing high resolution features on a substrate, the method comprising:
depositing a nanoparticle ink on a substrate, the nanoparticle ink comprising metal/semi-metal nanoparticles, a binder, and an adhesive compound; and
applying a laser beam directly on some or all of the deposited nanoparticle ink to define a high resolution print feature, wherein the laser beam is focused or masked to produce a high resolution laser spot; and
wherein the laser beam is configured to remove the nanoparticle coating or binder of the nanoparticle ink, thereby allowing the adhesive compound to bond to the nanoparticles, and wherein the laser beam is further configured to transform the ink to form a metal/semi-metal structure, thereby producing a metal/semi-metal structure of the width of the high resolution laser spot.

36. The method of claim 35, wherein the laser beam is a continuous wave laser beam.

37. The method of claim 35, wherein the laser beam emits in the visible or infra-red.

38. The method of claim 35, wherein the adhesive compound comprises an adhesion promoter and a surfactant.

39. The method of claim 35, further comprising:
washing the substrate to remove non-transformed deposited ink.

40. The method of claim 35, wherein a plurality of lasers are used to cure the deposited nanoparticle ink.

41. The method of claim 35, wherein the width of the laser spot is 5 microns or less in diameter.

42. The method of claim 38, wherein the adhesion promoter and/or surfactant are selected from the group comprising polysiloxanes, polyacrylates, polyurethanes, epoxy based materials, polymethacrylates, maleic anhydrides, polypyrroles, flurosurfactants, or a seed layer.

43. The method of claim 38, wherein the adhesion promoter and/or surfactant are selected from the group consisting of: Vinylbenzylaminoethylaminopropyltrimethoxysilane; Mercaptopropyltrimethoxysilane; Aminoethylaminopropyltrimethoxysilane-Methacryloxypropyltrimethoxysilane; Glycidoxypropyltrimethoxysilane; Bis-Triethoxysilylpropyldisulfidosilane; Hexamethyldisilazane (3,4 epoxycyclohexyl)-ethyltrimethoxysilane; Glycidoxypropylmethyldiethoxysilane; Glycidoxypropyltriethoxysilane; 3-methacryloxypropylmethyldimethoxysilane; 3-methacryloxypropyltrimethoxysilane; 3-methacryloxypropylmethyldiethoxysilane; 3-methacryloxypropyltriethoxysilane; 3-acryloxypropyltrimethoxysilane; N-2 (aminoethyl)3-aminopropylmethyldimethoxysilane; N-2(aminoethyl)3-aminopropyltrimethoxysilane; N-2(aminoethyl)3-aminopropyltriethoxysilane; 3-aminopropyltrimethoxysilane; 3-aminopropyltriethoxysilane; N-phenyl-3-aminopropyltrimethoxysilane; 3-chloropropyltrimethoxysilane; 3-mercaptopropylmethyldimethoxysilane; 3-isocyanatopropyltriethoxysilane; Tris(3-(trimethoxysilyl)propyl)isocyanurate; N-(3-methyldimethoxysilylpropyl)diethylenetriamine; N-(3-methyldiethoxysilylpropyl)diethylenetriamine; Methyldimethoxysilylpropylpiperazine; Methyldiethoxysilylmethylpiperazine; Trimethoxysilylpropylmorpholine; Methyldimethoxysilylpropylmorpholine; Hexanediaminomethyltriethoxysilane; Hexanediaminopropyltrimethoxysilane; [3-(trimethoxysilyl)propyl]aminocyclohexane; 3-thiocyanatopropyltriethoxysilane; 3-ureidopropyltrimethoxysilane; 1-[3-Triethoxysilyl)propyl]urea; 1-[3-(Triethoxysilyl)propyl]urea; 2-(3,4-epoxycyclohexyl)-ethyltrimethoxysilane; 2-(3,4-epoxycyclohexyl)-ethyltriethoxysilane; 3-ethacryloxypropyltrimethoxysilane; Methacryloxytrimethoxysilane; 3-methacryloxypropyltriethoxysilane; 3-methacryloxypropylmethyldimethoxysilane; 3-methacryloxypropylmethyldiethoxysilane; Methacryloxymethyltriethoxysilane; Methacryloxymethyl(methyl)dimethoxysilane; Methacryloxymethyl(methyl)diethoxysilane; 3-Acryloxypropyltrimethoxysilane; 2-cyanoethyldichloromethylsilane; Trimethyl(methylethylketoxime)silane; Tetra(methylethylketoxime)silane; Di-tertbutoxy-diacetoxysilane; Dimethyldiacetoxysilane; Triacetoxymethysilane; Tetraacetoxysilane; Ethyltriacetoxysilane; Vinyltriacetoxysilane; Bis(trimethylsilyl)acetylene; N,OBis(trimethylsilyl)acetamide; Trimethylsilyl-1,2,4-triazole; 1-(trimethylsilyl)imidazole; Tetra(acryloxy-ethoxy)silane; 5,5′-dimethyl-3,3′-bis(trimethylsilyl)biphenyl; and Tertbutylcyclopentadienyltrimethylsilane.

44. The method of claim 35, wherein the nanoparticle ink comprises a dispersion stabilizer.

45. The method of claim 35, Wherein the metal/semi-metal nanoparticles of the nanoparticle ink comprise a metal selected from the group of copper, gold, silver, aluminium, tantalum, molybdenum, and nickel.

46. The method of claim 35, wherein the nanoparticle ink comprises a plurality of metal nanomaterials comprising copper or silver, semimetals nanomaterials comprising silicon or nickel, or a mixture thereof.

47. The method of claim 35, wherein the nanoparticle ink comprises a plurality of semimetals nanomaterials comprising silicon.

48. The method of claim 47, wherein the silicon is doped with a dopant.

49. The method of claim 48, wherein the dopant comprises boron or phosphorous.

50. The method of claim 35, wherein the laser beam has a profile which is adapted to a top hat profile or improved uniformity over the typical Gaussian beam profile.

51. The method of claim 35, wherein the laser beam is adapted through an aperture or slit mask.

52. The method of claim 35, wherein the beam is adapted through a galvo scanner system.

53. The method of claim 35, wherein the laser is adapted through a lens system.

54. The method of claim 39, wherein washing the substrate to remove non-transformed deposited ink occurs after the application of the laser onto the substrate.

55. The method of claim 39, wherein washing the substrate to remove non-transformed deposited ink occurs before the application of the laser onto the substrate.

56. The method of claim 35, further comprising:
applying multiple nanoparticle ink layers with different compositions onto the substrate.

57. The method of claim 56, wherein a first layer promotes adhesion, and wherein subsequent layers comprise different doping concentrations or species.

58. The method of claim 35, wherein the substrate is selected from the group comprising: PET, PI, PE, PP, PVA, PI, SiN, ITO, alumina tile, and glass.

59. The method of claim 35, wherein printing high resolution features on a substrate creates a pn device.

60. An apparatus for printing high resolution features on a substrate, the apparatus comprising:
an ink depositing device for depositing a nanoparticle ink onto a substrate, wherein the nanoparticle ink comprises metal/semi-metal nanoparticles, an adhesive compound, and a binder;
a laser configured to apply a laser beam, directly on some or all of the deposited nanoparticle ink to define the high resolution print feature; and
a mask or focusing means configured to adapt the laser beam to produce a focused laser spot;
wherein the laser beam frequency is selected so as to remove the nanoparticle coating or binder of the nanoparticle thereby allowing the adhesive compound to bond to the nanoparticles, and wherein the laser beam is further configured to transform the ink to form a metal/semi-metal structure, thereby producing a metal/semi-metal structure the width of the laser spot.

61. The apparatus of claim 60, further comprising: one or more further lasers.

62. The apparatus of claim 61, further comprising:
a plurality of fiber optic cables or focusing lenses or masks, each fibre optic cable, focussing lens or mask configured to direct the laser beam emitted by a laser.

63. The apparatus of claim 62, wherein the one or more of the fibre optic cables or focussing lenses or masks is moveable.

64. The apparatus of claim 63, further comprising:
a computer configured to control the apparatus.

65. The apparatus of claim 64, wherein the computer is configured to control the movement of one or more of the fiber optic cables or focusing lenses or masks.

66. The apparatus of 64 wherein the computer is configured to accept an input indicative of a pattern to be printed by the apparatus and is further configured to move the fiber optic cables or focusing lenses or masks to replicate the inputted pattern.
